(19) United States
(12) Patent Application Publication
(10) Pub. No.: US 2004/0087252 A1
(43) Pub. Date: May 6, 2004

(54) Method for manufacturing organic light emitting diode with improved electrical leakage

(76) Inventor: Yan-Ming Huang, Fengyuan City (TW)

Correspondence Address: BIRCH STEWART KOLASCH & BIRCH, PO BOX 747, FALLS CHURCH, VA, 22040-0747, US

(21) Appl. No.: 10/283,259

(22) Filed: Oct. 30, 2002

(51) Int. Cl. B24B 1/00

(52) U.S. Cl. 451/41

(57) ABSTRACT

A method for manufacturing organic light emitting diode with improved electrical leakage employs a Chemical-Mechanical Polishing (CMP) process to flatten the surface of an Indium Tin Oxide (ITO) layer thereby to reduce leakage current occurred to an organic light emitting diode (OLED) element and increase efficiency and service life thereof.

### FIELD OF THE INVENTION

The present invention relates to a method for manufacturing organic light emitting diode (OLED) with improved electrical leakage and particularly a method that employs Chemical-Mechanical Polishing (CMP) technology to flatten the surface of an ITO (Indium Tin Oxide) layer to reduce electrical leakage occurred to the OLED.

### BACKGROUND OF THE INVENTION

Organic light emitting diodes (OLEDs) that are known today can be classified, based on the driving type, in simple matrix driving type and active matrix driving type. The commercialized OLEDs nowadays mostly are simple matrix driving type. This is mainly due to its simpler structure. It also does not use TFT (Thin-Film Transistor) or color filter, thus the cost is lower than LCD. However it has disadvantages such as not suitable for applications that require high resolution, consumes too much electric power in large dimension application, lower service life, accelerating degradation of the display elements, etc.

Among the factors that cause the phenomena of too much power consumption, shorter service life and degradation of the display elements that occur to the OLED, one major factor is that the surface of the transparent ITO anode used in the OLED is rough and uneven. There are general two approaches to overcome this problem:

1. Making a flat and more uniform ITO film by using methods other than the conventional RF sputter techniques, such as the HDAP technique developed by SHI Co.

2. Performing mechanical polishing on the rough film surface formed on the ITO glass to improve the flatness and evenness.

The first approach mentioned above requires expensive equipment for forming films. The second approach often generates scratches due to polishing problems and results in damages of the ITO surface and dropping of efficiency and production yield.

### SUMMARY OF THE INVENTION

Therefore the primary object of the invention is to resolve the aforesaid disadvantages. The invention employs Chemical-Mechanical Polishing (CMP) to flatten the surface of ITO layer to prevent the ITO layer in the OLED from generating point discharge thereby to reduce electrical leakage of the OLED.

In order to achieve the foregoing object, the invention employs CMP technique to flatten the ITO layer. The invention includes a polishing table for polishing the surface of the ITO layer and a holder for gripping the ITO layer. The holder grips the back side of the ITO layer and the front side of the ITO layer is pressed on a polishing pad located on the polishing table so that CMP process may be executed. During the CMP process, the polishing table and the holder rotate in one direction, and a reagent is dispensed continuously through a delivery pipe to the polishing table. The CMP technique uses the chemical reaction generated by the reagent and the mechanical polishing occurred to the ITO layer on the polishing table to flatten and smooth the rough and uneven surface of the ITO layer.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of the structure of a conventional OLED.

FIG. 2 is a schematic view of the structure of an OLED of the invention.

FIGS. 3A and 3B are a simplified top view and a side view of the equipment of CMP process of the invention.

FIG. 4 is a photo taken by an AFM showing the surface of an ITO layer before being polished by means of the invention.

FIG. 5 is a photo taken by an AFM showing the surface of an ITO layer after being polished by means of the invention.

FIG. 6 is a chart showing graphs of electrical leakage before and after the surface of the ITO layer being polished.

### DETAILED DESCRIPTION OF THE INVENTION

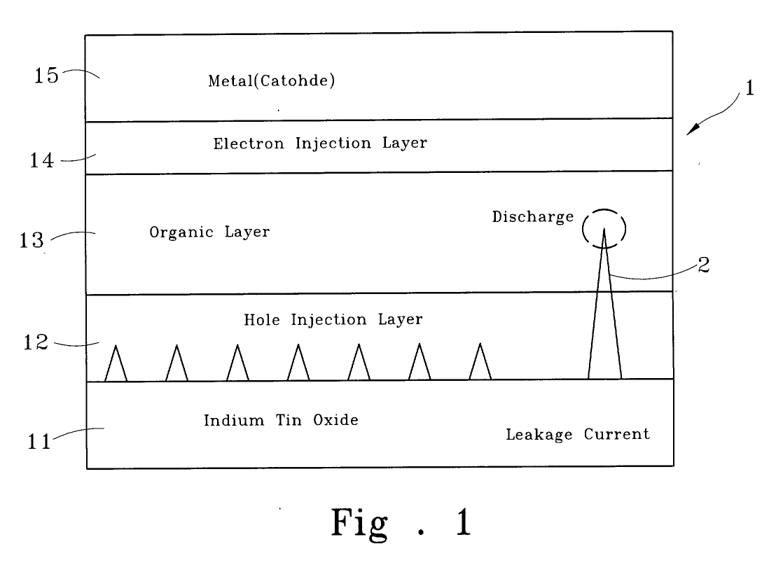

Referring to FIG. 1, a conventional OLED 1 includes at least one ITO layer 11, a HIL (Hole Injection layer) 12 located above the ITO layer 11, an organic layer 13 located above the HIL layer 12, an EIL (Electron Injection Layer) layer 14 above the organic layer 13, and a metal layer 15 located above the EIL layer 14. The OLED element serve as a carrier to be injected into the organic layer for coupling therewith to transfer energy and generate light. The injection effectiveness of the carrier greatly affects the bonding interface between the surface of the ITO layer 11 and the organic layer 13. The thickness of the organic layer 13 is about 1000 A-1500 A. The HIL layer 12 adjacent to the ITO layer 11 has a thickness about 150 A. As the thickness of the HIL layer 12 is very small and the surface of the ITO layer is rough and uneven, the jutting peak 2 on the surface of the ITO layer 11 tends to generate point discharge and leakage current. As a result, greater power consumption and cross-talk are prone to occur to the OLED element 1.

The invention aims at preventing the foregoing phenomena from occurring to the ITO layer 11 that might result in damage of the OLED element 1 or cross-talk. The invention also enables the EIL layer 14 to function properly. The surface roughness of the ITO layer 11 in the OLED must be less than 10 A. The flattened surface of the ITO layer 11 can reduce the probability of forming crystallization centers. Therefore the amorphous organic layer 13 above the ITO layer 11 is more stable and has a longer service life. However, the surface roughness of ITO layer 11 now being used on STN-LCD and TFT-LCD is about 30 A-50 A. This condition is not applicable to OLED under the strict demand imposed to the OLED element 1.

The OLED element 1 has a strict demand for surface roughness on the ITO layer 11 being used. The average value must be lower than 1.5 nm, and a high degree of uniformity is also required for the roughness. In order to achieve flattened and smooth surface on the ITO layer 11, the invention employs CMP technique. The CMP technique is widely used in the semiconductor IC manufacturing processes. However it is rarely used in flat display panel production. Applicant discovers that after the surface of the ITO layer 11 of OLED element 1 is flattened and polished by employing the CMP technique, leakage current occurred to the element decreases and efficiency is improved, and service life also increases.

The CMP process mentioned above is one of the flatten processes known in the art that is quite easy to understand. It adopts a principle substantially like a common “grinding knife” practice. In the CMP process, a suitable reagent is used to aid grinding operation to polish the uneven surface contour of the ITO layer 11. Once the parameters of the process are properly controlled, the surface formed by CMP can reach the flatness of 94% or higher.

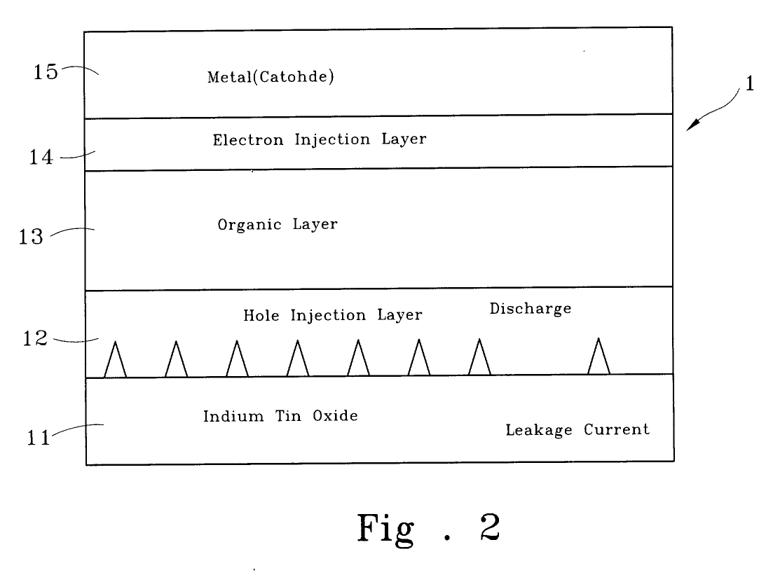

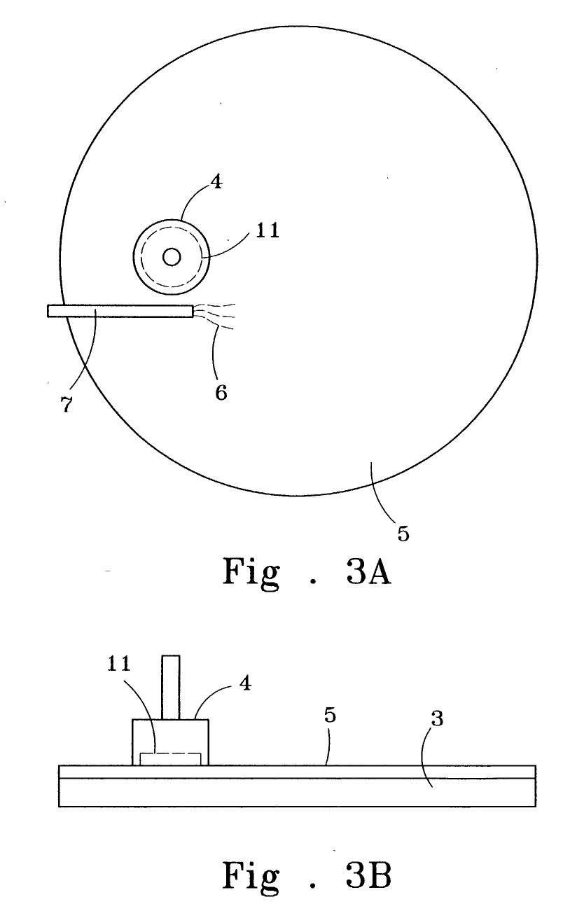

Refer to FIGS. 3A and 3B for a simplified apparatus for CMP flattening process. It basically includes a polishing table 3 for polishing the ITO layer 11 and a holder 4 for gripping the ITO layer 11. The holder 4 grips the back side of the ITO layer 11 and the front side of the ITO layer 11 is pressed on a polishing pad 5 located on the polishing table 3 so that the CMP process may be executed. During the CMP process, the polishing table 3 and the holder 4 rotate in one direction, and a slurry 6 is dispensed continuously through a delivery pipe 7 to the polishing table 3. The CMP technique uses the chemical reaction generated by the reagent and the mechanical polishing occurred to the ITO layer 11 on the polishing table 3 to flatten and smooth the rough and uneven surface of the ITO layer 11 (as shown in FIG. 2).

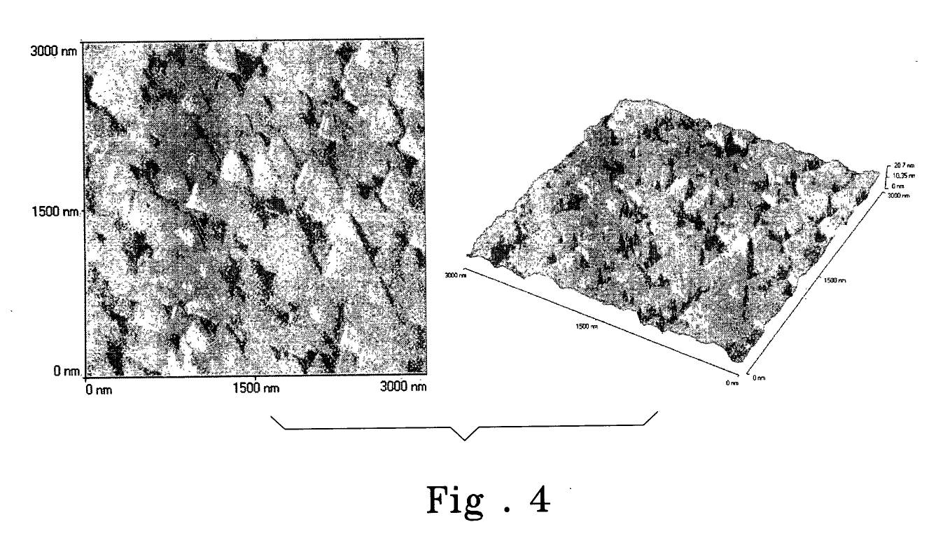

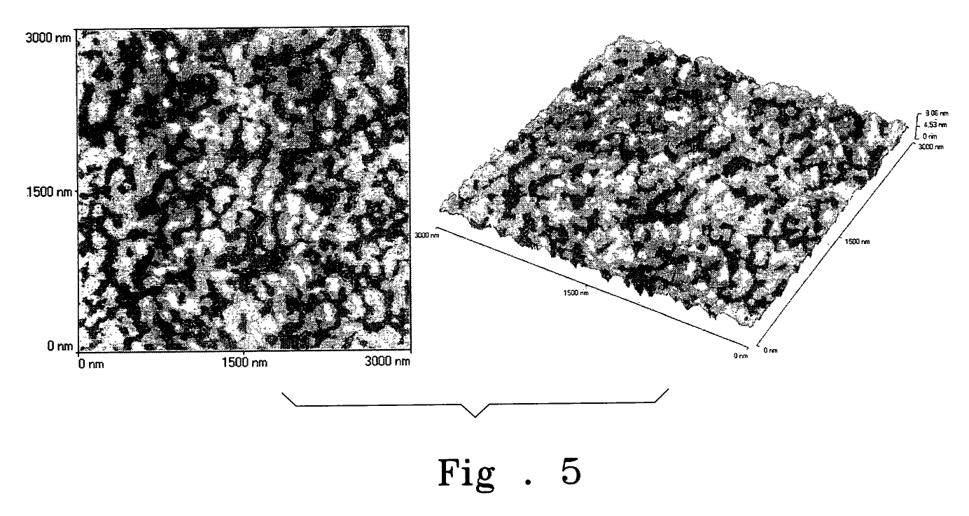

Refer to FIGS. 4 and 5 for comparisons of the ITO layer surface before and after being polished by means of the invention. As shown in the photos, before the ITO layer is polished, the surface roughness Ra is about 2 nm, and Rz is 11.6 nm. After having been polished by the CMP process, the Ra is 0.87 nm and Rz is 4.67 nm. The surface roughness of the ITO layer 11 is greatly improved after polishing.

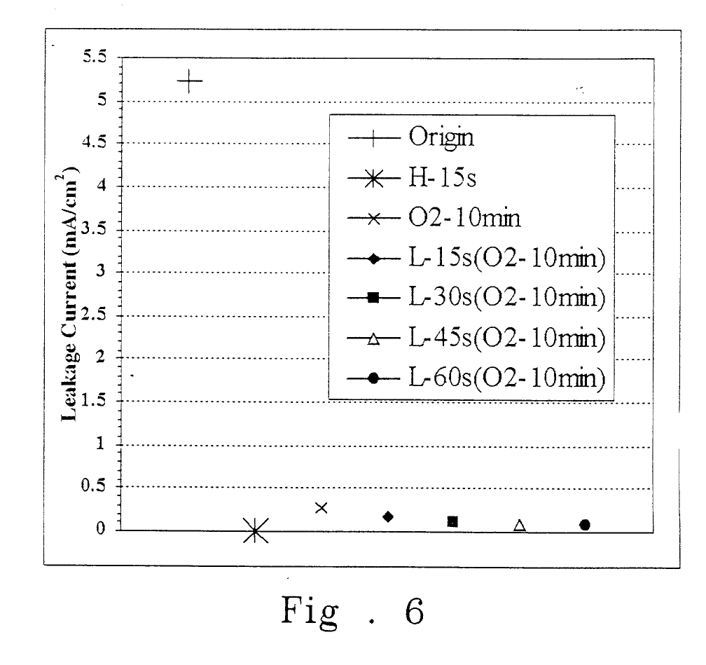

Refer to FIG. 6 for comparisons of leakage current before and after the polishing of the ITO layer surface. The OLED element 1 made by including the ITO layer 11 without prior polishing was detected with leakage current of 5.2 mA/cm2. The OLED element 1 made by including the ITO layer 11 that has been processed by the CMP technique was detected with leakage current as low as 0-0.5 mA/cm2.

The results of adopting the invention may further be seen from the following table:

| | | 15 | 30 | 45 | 60 |
|---|---|---|---|---|---|
| CMP processes | No CMP | seconds | seconds | seconds | seconds |
| Leakage current | 5.2 | 0.15 | 0.12 | 0.1 | 0.12 |
| (mA/cm2) | | | | | |

Based on discussions set forth above, it is obvious that after the ITO layer 1 was polished by CMP technique, leakage current occurred to the OLED element 1 is greatly reduced. And efficiency and service life of the OLED element 1 increased. Thus the invention can provide a great benefit to the industry.

What is claimed is:

1. A method for manufacturing organic light emitting diode with improved electrical leakage for reducing leakage current of an organic light emitting diode (OLED), comprising steps of:
providing an Indium Tin Oxide (ITO) layer and forming a rough surface on the ITO layer;
flattening and polishing the rough surface of the ITO layer through a Chemical-Mechanical Polishing (CMP) process; and
forming the OLED on the ITO layer after the surface thereof has been flattened.

2. The method of claim 1, wherein the roughness of the flattened surface of the ITO layer is at least less than 10 A.

3. The method of claim 1, wherein the CMP process for flattening includes equipment of one polishing table, a holder, a polishing pad and a delivery pipe.

4. The method of claim 3, wherein the delivery pipe transports a reagent.

5. The method of claim 4, wherein the reagent is a slurry.
